(19) United States
(12) Patent Application Publication
(10) Pub. No.: US 2005/0117301 A1
(43) Pub. Date: Jun. 2, 2005

(54) Channeled heat sink and chassis with integrated heat rejecter for two-phase cooling

(76) Inventors: Ravi Prasher, Tempe, AZ (US); Ravi Mahajan, Tempe, AZ (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/029,136

(22) Filed: Jan. 3, 2005

Related U.S. Application Data
(62) Division of application No. 10/404,295, filed on Mar. 31, 2003.

(51) Int. Cl. H05K 7/20

(52) U.S. Cl. 361/699; 361/704

(57) ABSTRACT

A channeled heat sink and a device chassis having one or more integral condensing volumes suited for heat rejecters in conduction with two-phase cooling loops. The channeled heat sink includes a base from which a plurality of hollowed fins extend. Each hollowed fin defines an internal channel having walls configured to condense a working fluid from a vapor phase upon entering the channel into a liquid phase upon exiting the channel. The chassis comprises a shell formed from a base coupled to a plurality of walls. At least one condensing volume is formed in the base and/or the walls of the chassis. The condensing volume is configured to condense a working fluid from a vapor phase to a liquid phase as the working fluid is passed through it.

### FIELD OF THE INVENTION

The field of invention relates generally to cooling electronic apparatus' and systems and, more specifically but not exclusively relates to two-phase cooling technology.

### BACKGROUND INFORMATION

Components in computer systems are operating at higher and higher frequencies, using smaller die sizes and more densely packed circuitry. As a result, these components, especially microprocessors, generate large amounts of heat, which must be removed from the system's chassis so that the components do not overheat. In conventional computer systems, this is accomplished via forced air convection, which transfers heat from the circuit components by using one or more fans that are disposed within or coupled to the chassis to draw air over the components through the chassis. To further aid the heat removal process, heat sinks are often mounted to various high-power circuit components to enhance natural and forced convection heat transfer processes. Heat sinks comprising of an array of fins having a height of approximately 1-2 inches are commonly used to cool microprocessors in desktop systems, workstations, and pedestal-mounted servers. The heat sinks provide significantly greater surface areas than the components upon which they are mounted.

For example, a typical processor cooling solution that employs a heatsink is shown in FIG. 1. The cooling solution is designed to cool a processor die 100, which is flip-bonded to a substrate 102 via a plurality of solder bumps 104. Typically, an epoxy underfill 106 is employed to strengthen the interface between die 100 and substrate 102. Substrate 102, in turn, is mounted to a chip carrier 108 via a plurality of solder balls 110. The upper side of the die is thermally coupled to a copper heat spreader 112 via a first layer of thermal interface material (TIM) 114. Similarly, a heat sink 118 is thermally coupled to the copper heat spreader via a second layer of TIM 118.

During operation, the processor die generates heat due to resistive losses in its circuitry. This heats up the processor. Since heat flows high temperature sources to lower temperature sinks, heat is caused to flow through TIM layer 114 to copper spreader 112. In turn, heat from the spreader flows through TIM layer 118 to heat sink 116. The heat sink, in turn, is cooled by air that flows over the heat sink's fins 120, either via natural convection or forced convection. Generally, the rate of cooling is a function of the fin area and the velocity of the air convection.

Thermal solutions are even more difficult for smaller thin form-factor based devices, such as laptop computers and handheld devices and the like. In this instance, the amount of space available for heat sinks and heat spreaders is minimal, thereby causing the heat transfer capacity to be significantly reduced. The power available to drive fans is also significantly reduced. Even with the use of lower-power dies, the reduced heat transfer capacity often leads to the processors running derated speeds via self-regulation in response to over temp conditions.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein like reference numerals refer to like parts throughout the various views unless otherwise specified:

FIG. 1 is a cross-section view of a conventional cooling assembly employing a metallic spreader and heat sink;

FIG. 2a is a schematic diagram of a closed loop cooling system employing a microchannel heat exchanger;

FIG. 2b is a cross-section view of a conventional microchannel heat exchanger that may be employed in the closed loop cooling system of FIG. 2a;

FIGS. 3a and 3b are external and partial cut-away isometric views of a channeled heat sink in accordance with one embodiment of the invention;

FIGS. 3c, 3d, and 3e show respective heat sink channel configurations corresponding to the channeled heat sink of FIGS. 3a and 3b;

FIG. 4a is an isometric view of a chassis including an integrated channeled heat sink in accordance with one embodiment of the invention;

FIG. 4b shows a close-up isometric cut-away view corresponding to the chassis of FIG. 4a;

FIG. 5a is an isometric view of a chassis including an integrated channeled heat sink in accordance with one embodiment of the invention;

FIG. 5b shows an isometric cut-away view corresponding to the chassis of FIG. 5a;

FIG. 6a is a cross-section view of a microchannel heat exchanger that is integrated with an integrated circuit (IC) die in accordance with an embodiment of the invention, wherein a thermal mass including a plurality of open microchannels is coupled to the IC die using a solder and the bottom surfaces of the microchannels comprise the solder material;

FIG. 6b is a cross-section view of a exemplary IC package in which the components of FIG. 6a are coupled to a substrate and a chip carrier;

FIG. 7a is cross-section view of a microchannel heat exchanger that is coupled to an IC die via a thermal interface material layer in accordance with an embodiment of the invention, wherein the microchannel heat exchanger includes a thermal mass having a plurality of open microchannel covered by a plate;

FIG. 7b is a cross-section view of a exemplary IC package in which the components of FIG. 7a are coupled to a substrate and a chip carrier;

FIG. 8a is a plan view of a microchannel heat exchanger including parameters that define the configuration of the heat exchanger;

FIG. 8b is a cross section view illustrating further details of the channel configuration parameters of FIG. 8a;

FIG. 9 is a schematic diagram showing an exemplary cooling system in which embodiments of the invention may be employed.

### DETAILED DESCRIPTION OF PREFERRED EMBODIMENTS

Embodiments of closed loop two-phase cooling system components, including channeled heat sinks and device chassis with integrated heat rejection features are described herein. In the following description, numerous specific details are set forth to provide a thorough understanding of embodiments of the invention. One skilled in the relevant art will recognize, however, that the invention can be practiced without one or more of the specific details, or with other methods, components, materials, etc. In other instances, well-known structures, materials, or operations are not shown or described in detail to avoid obscuring aspects of the invention.

Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

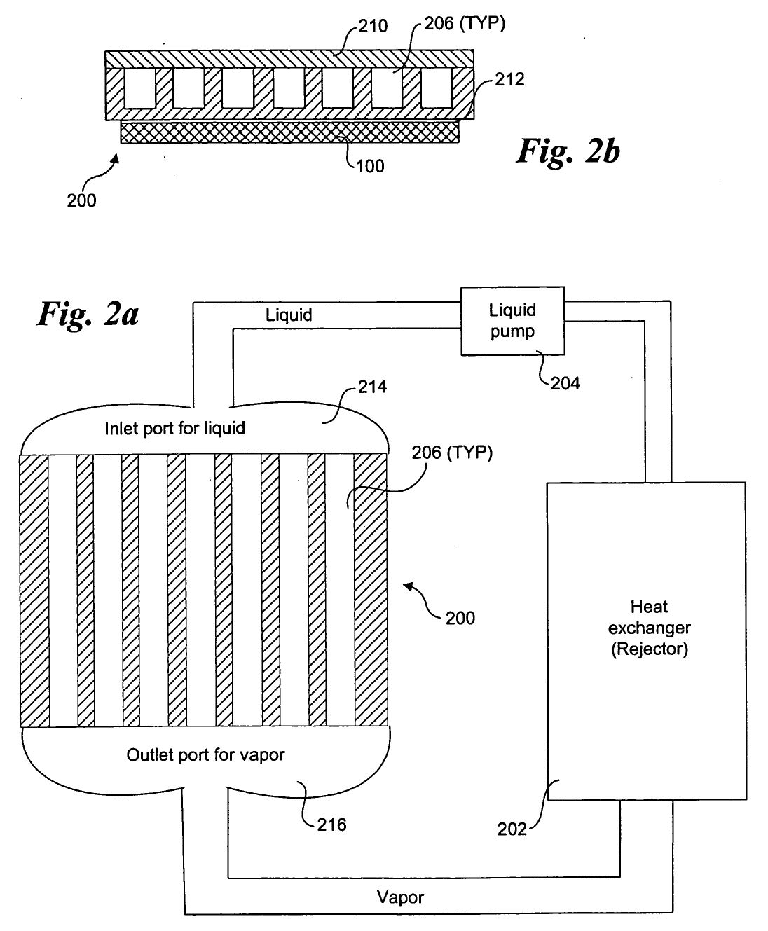

Recently, research efforts have been focused on providing thermal solutions for densely-packaged high-power electronics. A leading candidate emerging from this research is the use of two-phase convection in micromachined silicon heat sinks, commonly referred to as microchannels. A typical configuration for a microchannel-based cooling system is shown in FIGS. 2a and 2b. The system includes a microchannel heat exchanger 200, a heat rejecter 202, and a pump 204. The basic premise is to take advantage of the fact that changing a phase of a fluid from a liquid to a vapor requires a significant amount of energy, known as latent heat, or heat of vaporization. Conversely, a large amount of heat can be removed from the fluid by returning the vapor phase of back to liquid. The microchannels, which typically have hydraulic diameters on the order of hundred-micrometers, are very effective for facilitating the phase transfer from liquid to vapor.

In accordance with typical configurations, microchannel heat exchanger 200 will comprise a plurality of microchannels 206 formed in a block of silicon 208, as shown in FIG. 2b. A cover plate 210 is then placed over the top of the channel walls to formed enclosed channels. Generally the microchannel heat exchanger performs the function of a heat sink or heat spreader/heat sink combination. Accordingly, in FIG. 2b the microchannel heat exchanger is shown as thermally coupled to a die 100 via a TIM layer 212. In an optional configuration, a processor die with an increased thickness may include channels formed in the processor die silicon itself.

As the die circuitry generates heat, the heat is transferred outward to the microchannel heat exchanger via conduction. The heat increases the temperature of the silicon, thereby heating the temperature of the walls in the microchannels. Liquid is pushed by pump 204 into an inlet port 214, where it enters the inlet ends of microchannels 206. As the liquid passes through the microchannels, further heat transfer takes place between the microchannel walls and the liquid. Under a properly configured heat exchanger, a portion of the fluid exits the microchannels as vapor at outlet port 216. The vapor then enters heat rejecter 202. The heat rejecter comprises a second heat exchanger that performs the reverse phase transformation as microchannel heat exchanger 200—that is, it converts the phase of the vapor entering at an inlet end back to a liquid at the outlet of the heat rejecter. In general, the heat rejecter will comprise a volume or plurality of volumes having walls on which the vapor condenses. If the walls are kept at a temperature lower than the saturation temperature (for a given pressure condition), the vapor will condense, converting it back to the liquid phase. The liquid is then received at an inlet side of pump 204, thus completing the cooling cycle.

A significant advantage of the foregoing scheme is that is moves the heat rejection from the processor/die, which is typically somewhat centrally located within the chassis, to the location of the heat rejecter heat exchanger, which can be located anywhere within the chassis, or even externally. Thus, excellent heat transfer rates can be obtained without the need for large heatsinks/spreaders and high airflow rates.

While many research efforts have focused on modeling two-phase convection and simulating microchannel heat exchanger performance at the heat source (e.g., when employed for cooling a large IC, such as a processor), little effort has been targeted toward the heat rejection portion of the cycle. As a result, typical heat rejecter components/subassemblies are generally large and inefficient. Furthermore, such research heat rejecter configurations are not suitable for use in many portable electronic devices, especially those devices with thin form factors.

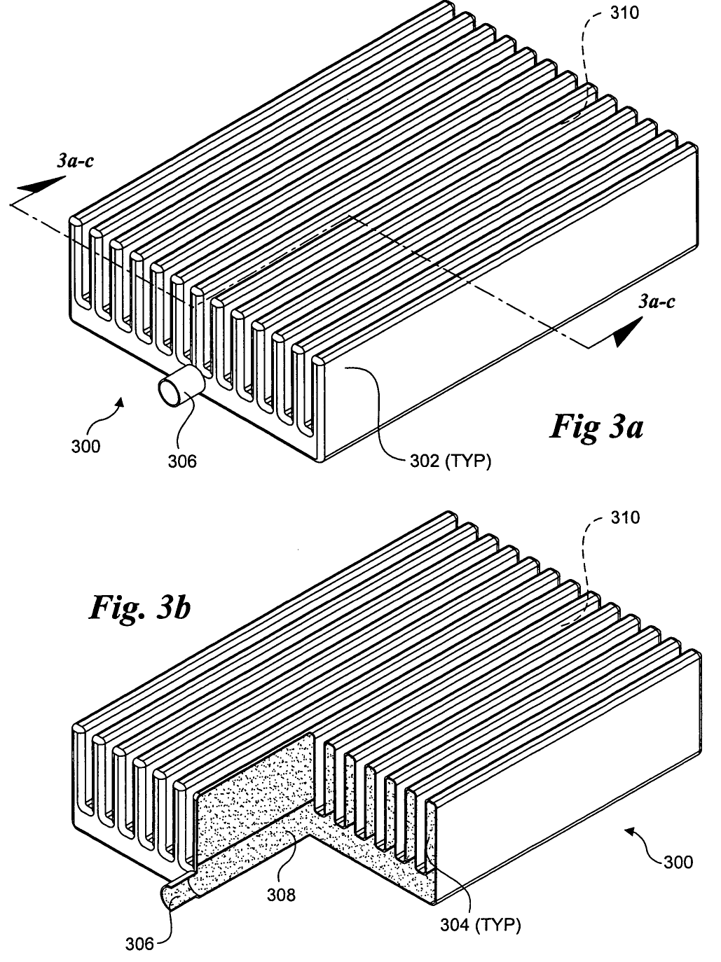

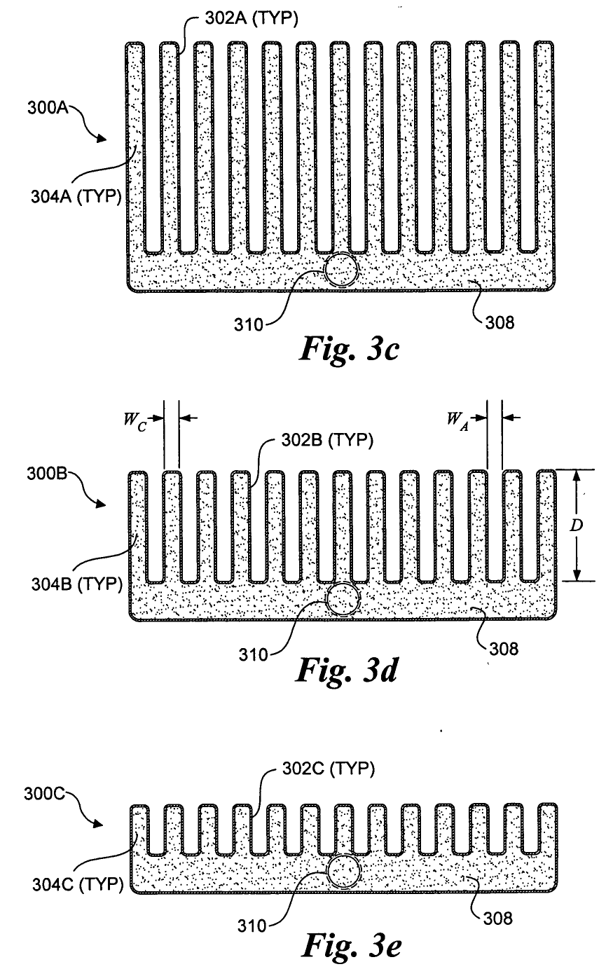

In accordance with a first aspect of the invention, heat rejecter components are disclosed herein that provide substantial reduction in overall size and increased efficiency. In one embodiment, a “channeled” or hollowed finned heat sink is employed for the heat rejecter. Exemplary configurations for a channeled heat sink 300 of such a configuration are shown in FIGS. 3a-e. The channeled heat sink includes a plurality of hollow fins 302 having respective channels 304 formed therein. Incoming working fluid in the vapor state is received at an inlet 306 and enters a reservoir 308. The vapor expands and condenses on the walls of channels 304, failing down the walls as a liquid that is collected at the bottom of reservoir 308. The liquid exits the channeled heat sink at an outlet 310 (hidden from view in FIGS. 3a-b).

Three exemplary channel configurations corresponding to channeled heat sink embodiments 300A, 300B, and 300C are shown in FIGS. 3c, 3d, and 3e, respectively. In general, the configuration of the channeled heat sink is defined by the interior width of the channels W_{C}, the width of the air gap between fins W_{A}, and the depth of the fins D. A wide range of values may be used for each of these parameters, depending on the available space, required cooling rate, and convection considerations (such as whether forced air convection is available). Generally, unlike with the microchannel heat exchangers discussed below, there is more space in which to place the channeled heat sink. Thus, the size of the channels and corresponding fins may be significantly larger than the size of the microchannels discussed below. However, in cases in which a limited amount of space is available, the size of the channels in the channeled heat sink may be similar to those employed for the microchannel heat exchangers.

Generally, the channeled heat sink may be formed using well-known manufacturing techniques targeted towards thin-walled components, and may be made from a variety of materials, including various metals and plastics. The manufacturing techniques include but are not limited to casting (e.g., investment casting) and molding (e.g., injection molding, rotational molding for plastic components), and stamping (for metal components). Operations such as brazing may also be employed for assembling multi-piece channeled heat sinks. In instances in which the heat sink is formed from a plastic, the plastic may act as a carrier in which metal particles are embedded to enhance the conductive heat transfer rate for the heat sink.

In accordance with an extension of the channeled heat sink principles, heat rejection features may be built into the chassis of an electronic device that employs two-phase cooling. In general, the chassis includes at least one integrated condensing volume that is configured such that a vapor phase of a working fluid that enters the condensing volume is condensed along the walls of the volume, converting it into a liquid phase that falls to the bottom of the walls, where it is collected. The liquid working fluid then exits the condensing volume.

In one set of embodiments, channeled heat sinks having similar configurations to channeled heat sink 300A are “integrated” into the chassis. As used herein, the term “integrated” implies that the channeled heat sink is an integral part of the chassis, that is it comprises either structure portion of the chasses or is coupled to the chassis in a manner in which it functions as a structural element. For example, the channeled heat sink may be directly formed in conjunction with the formation of the chassis, or may comprise a separately-formed part that is subsequently added to the chassis during a separate operation. Another defining feature is, upon assembly, at least one surface of the channeled heat sink comprises an external portion of the chassis base and/or sidewall.

In general, the chassis and integrated channeled heat sink may be made of the same material, or different materials. Depending on the forming technology, the chassis may be formed of a single part, or multiple assembled parts. In general, the chassis may be made of plastic or a metal using well-known forming practices appropriate for the selected chassis material.

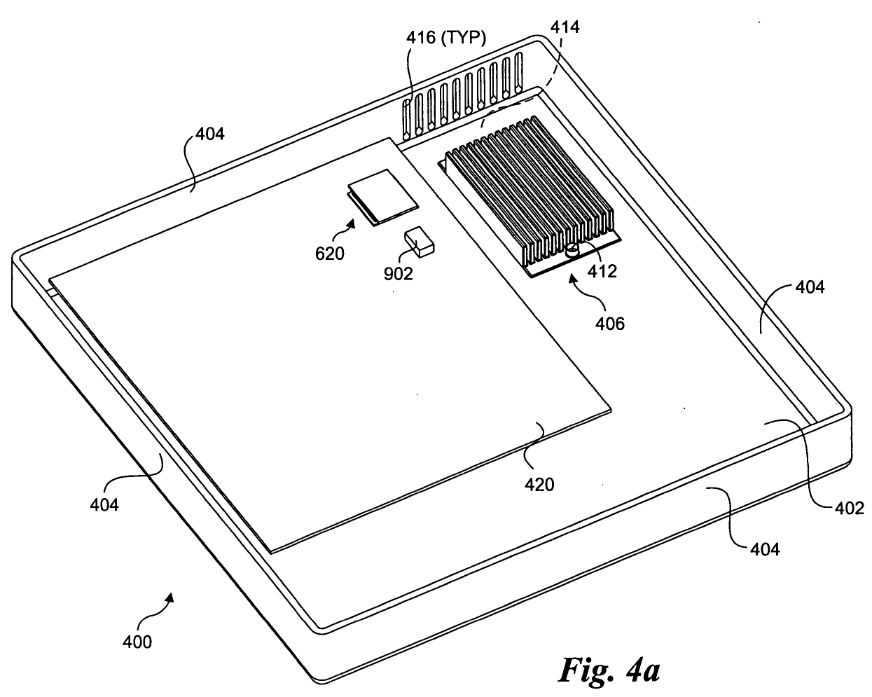

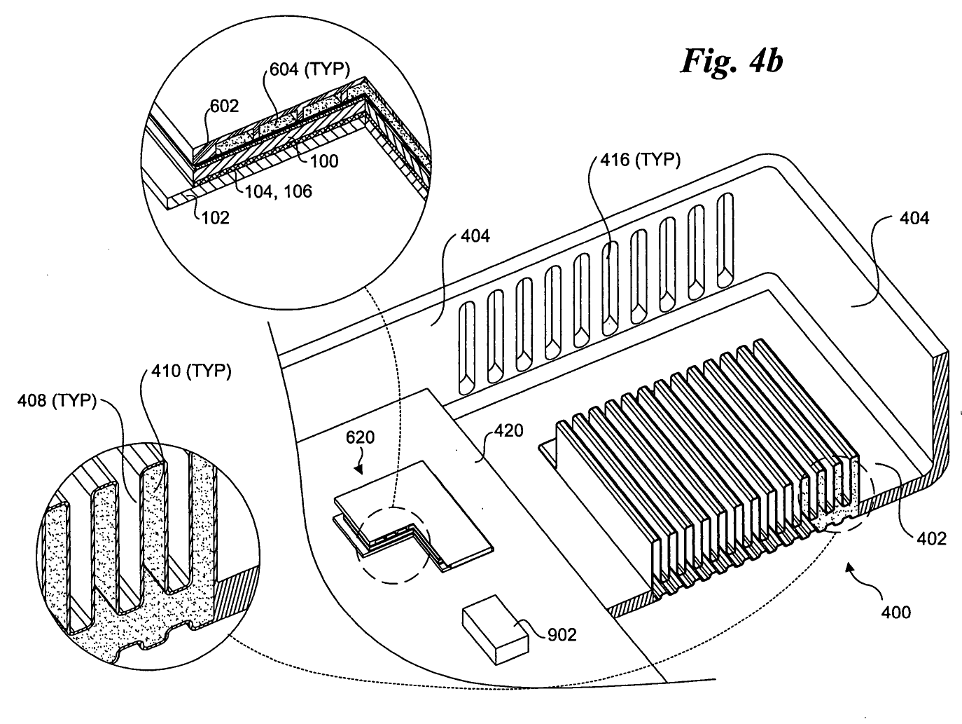

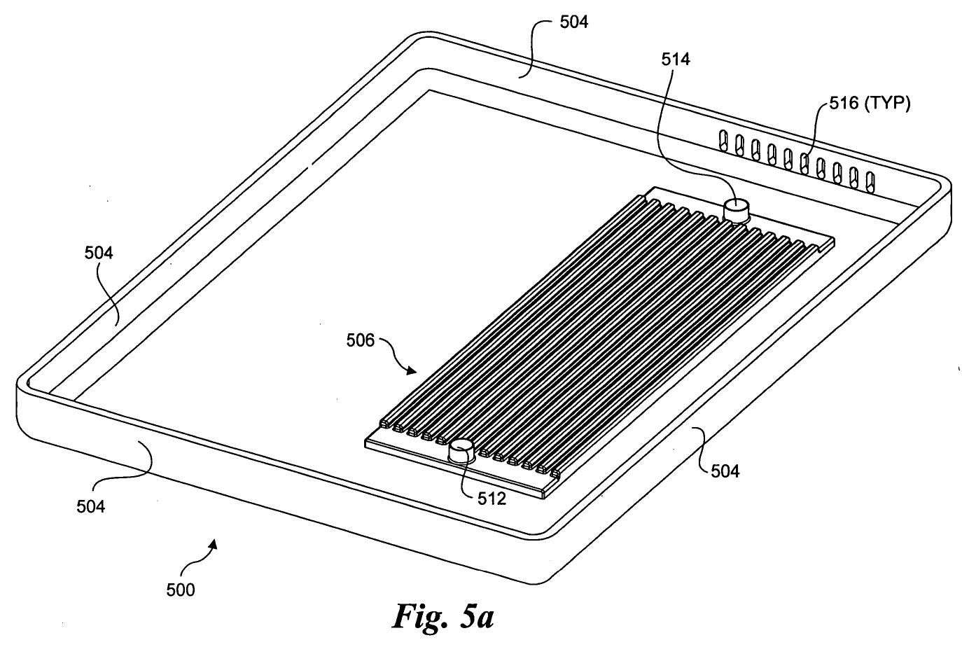

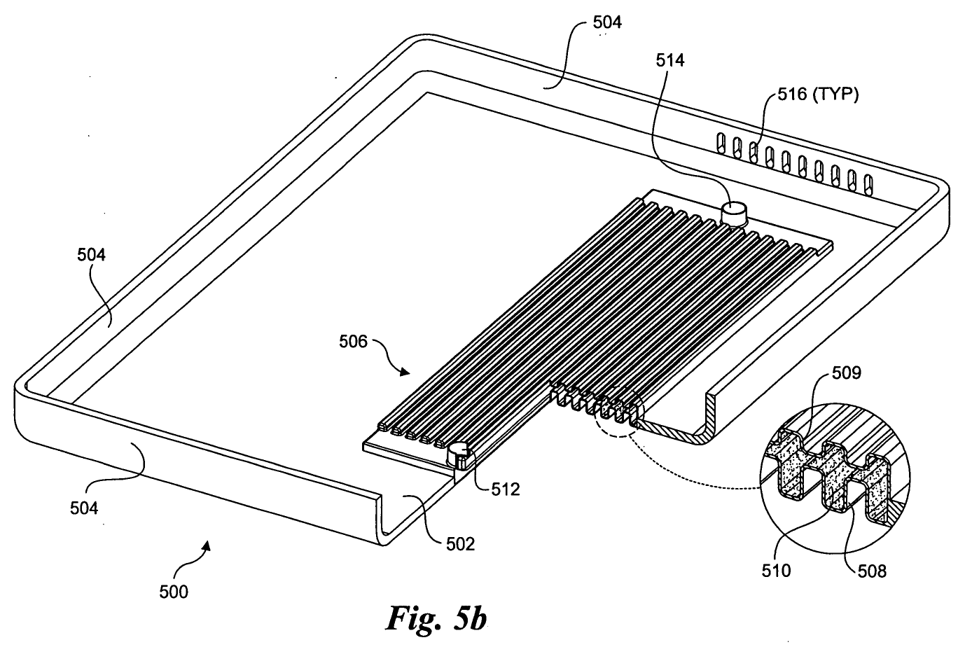

A first exemplary embodiment of a chassis 400 with an integrated heat rejecter is shown in FIGS. 4a and 4b. The chassis comprises a base 402 to which a four walls 404 are coupled to form a shell configuration. This type of configuration is commonly used for many thin form-factor electronic devices, such as laptop computers, PDA's, pocket PC's, cell-phones, and the like. In the illustrated embodiment, a channeled heat sink 406 is formed in base 402. It is contemplated that a similar channeled heat sink may be formed in one or more of walls 404, or the channeled heat sink may be integral to both the base and a wall. As shown in further detail in FIG. 4B, the integrated channeled heat sink includes a plurality of hollowed fins 408 defining respective condensing volumes comprising channels 410. In the illustrated embodiment, the primary portions of the fins extend upward (inward) toward an inner volume of the shell. In an optional configuration as discussed below with reference to FIGS. 5A and 5B, the primary portion of the fins extend downward (outward) from the shell's inner volume. As a further option, portions of the hollowed fins may extend both inwardly and outwardly.

Each condensing volume (i.e., channel) will have one end fluidly coupled to an inlet 412, while the other end of the channel is fluidly coupled to an outlet 414. A portion of the working fluid enters inlet 412 and is distributed to the channels in a vapor phase, which condenses to a liquid along the channel walls, falling to the base of the channel. The liquid working fluid collected at the base of the channels then exits the heat sink at outlet 414.

As an optional feature, the chassis may include one of more slots 416 defined in one or more walls 404 and/or base 402. The slots enhance airflow across the heat sink fins, thereby increasing the rate of heat rejection. As another option, a fan (not shown) may be employed to draw air across the fins, exiting through slots 416.

FIG. 4a illustrates a typical component packaging configuration for an exemplary device employing chassis 400. This includes a main board (e.g., motherboard) 420 to which an IC package 620 and a pump 902 are mounted. For the purpose of clarity, ducting (i.e., fluid couplings) between the components is not shown herein—the particular ducting configuration employed is somewhat flexible, and those skilled in the art will be able to determine appropriate sizes and configurations for the ducting. The IC package includes an IC die thermally coupled to a microchannel heat exchanger. Further details of the IC package and pump components are described below.

A second exemplary integral channeled heat sink configuration corresponding to a chassis 500 is shown in FIGS. 5A and 5B. In this instance, the chassis comprises a shell having a very thin form factor. The shell is formed from a base 502 coupled to walls 504. As shown in detail in FIG. 5B, an integral channeled heat sink 506 is formed in the base of the chassis. The channeled heat sink has a profile comprising outwardly extending hollowed fins 508 and inwardly extending hollowed fins 509, collectively defining condensing volumes comprising channels 510. As a further aspect of the illustrated configuration, the ends of the outwardly extending hollowed fins 508 are substantially flush with a plane coincident with the exterior of base 502. Channeled heat sink 506 further includes an inlet 512 and an outlet 514. Chassis 500 may optionally include slots 516 and a fan (not shown).

In general, when properly configured, the heat rejecters described herein may be used with most any two-phase cooling loop components, such as those discussed above with reference to FIGS. 2a-b. More particularly, embodiments of exemplary microchannel heat exchangers and corresponding cooling solutions implementing the chassis heat rejecters are now disclosed.

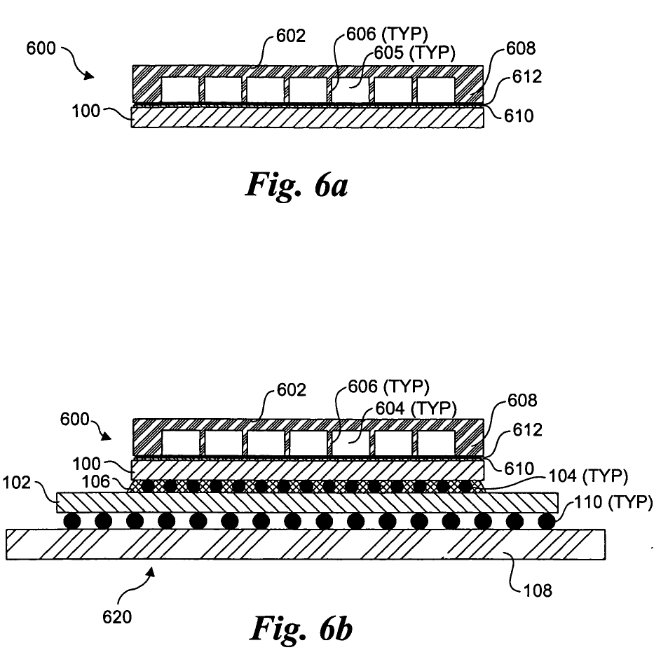

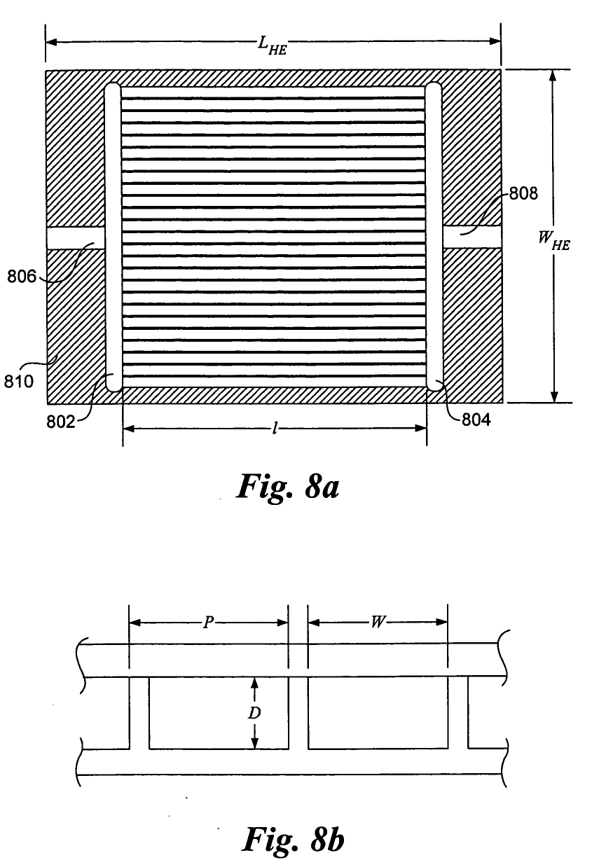

An integrated microchannel heat exchanger 600 is shown in FIG. 6a. The microchannel heat exchanger includes a metallic thermal mass 602 in which a plurality of microchannels 604 are formed. Metallic thermal mass 602 may be configured in various shapes, including the block shape shown in FIGS. 6a and 6b. For point of illustration, the size and configuration of the microchannels formed in the metallic thermal mass are exaggerated for clarity; details of exemplary channel configurations are discussed below with reference to FIGS. 8A and 8B. In accordance with principles of the embodiment, the thermal mass is mounted over an integrated circuit (IC) die 100 such that a hermetic seal is formed between the bases of internal channel walls 606 and external channel walls 608 and the top of the die. Thus, each of channels 604 comprises a closed volume configured to facilitate two-phase heat transfer in the manner discussed above. This microchannel heat exchanger configuration is termed “integrated” because the IC die surface (or a layer coupled to the IC die surface) forms an integral part (i.e., the base) of the microchannels.

In the embodiment illustrated in FIG. 6a, the hermetic seal is formed by soldering metallic thermal mass 602 to die 100. In particular, the bases of internal channel walls 606 and external channel walls 608 are soldered to a layer of solderable material 610 affixed to the top side of the die using a solder 612. Generally, solderable material 610 may comprise any material to which the selected solder will bond. Such materials include but are not limited to metals such as copper (Cu), gold (Au), nickel (Ni), aluminum (Al), titanium (Ti), tantalum (Ta), silver (Ag) and Platinum (Pt). In one embodiment, the layer of solderable material comprises a base metal over which another metal is formed as a top layer. In another embodiment, the solderable material comprises a noble metal; such materials resist oxidation at solder reflow temperatures, thereby improving the quality of the soldered joints.

Generally, the layer (or layers) of solderable material may be formed over the top surface of the die 100 using one of many well-known techniques common to industry practices. For example, such techniques include but are not limited to sputtering, vapor deposition (chemical and physical), and plating. The formation of the solderable material layer may occur prior to die fabrication (i.e., at the wafer level) or after die fabrication processes are performed.

In one embodiment solder 612 may initially comprise a solder preform having a pre-formed shape conducive to the particular configuration of the bonding surfaces. The solder preform is placed between the die and the metallic thermal mass during a pre-assembly operation and then heated to a reflow temperature at which point the solder melts. The temperature of the solder and joined components are then lowered until the solder solidifies, thus forming a bond between the joined components. Furthermore, the solidified solder forms a hermetic seals between the bottom of the internal and external walls and the top of the die.

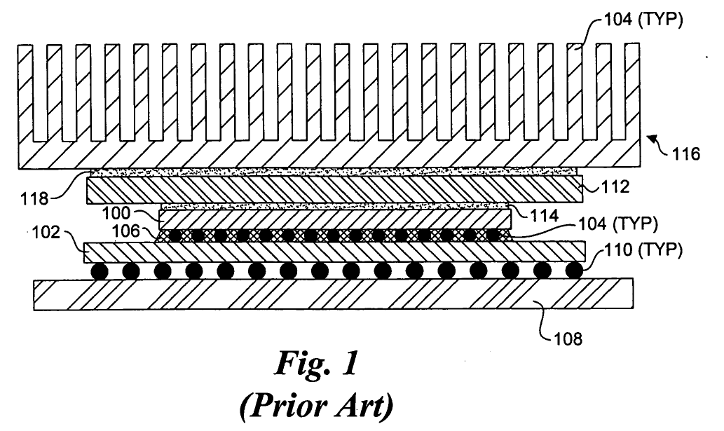

An IC package 620 corresponding to an exemplary use of microchannel heat exchanger 600 is shown in FIG. 6d. The lower portion of the package is similar to the assembly shown in FIG. 1. Accordingly, IC die 100 is flip-bonded to substrate 102 via solder bumps 104, while substrate 102 is secured to chip carrier 108 via a plurality of solder balls 110. In general, chip carrier 108 represents various types of base components used in IC packaging, including leaded and non-leaded chip carriers, ball grid arrays (BGA's), pin grid arrays (PGA's) and the like. For clarity, many of the chip carriers illustrated herein due not show any connection features, although it will be understood that such features exist in an actual package.

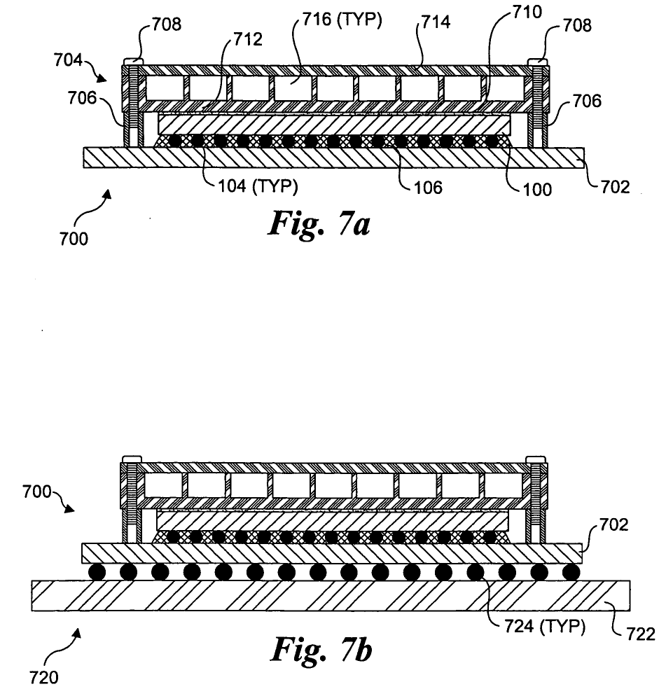

In an alternative scheme, depicted in FIGS. 7a and 7b, a separate microchannel heat exchanger is thermally coupled to an IC die via a TIM layer, while the heat exchanger is operatively coupled to the die via a physical coupling to a substrate on which the die is mounted. For example, in the microchannel heat exchanger/die subassembly 700 illustrated in FIG. 7a, an IC die 100 is mounted to a substrate 702. For illustrative purposes, the die is shown to be flipped-bounded to the substrate; however, this is merely an exemplary mounting scheme, and is not meant to be limiting. A microchannel heat exchanger 704 is then operatively coupled to the die via a physical coupling to substrate 702. In general, this physically coupling can be provided by one of many well-known assembly techniques, such as via appropriate fasteners and/or adhesives. In the illustrated embodiment, a plurality of standoffs 706 are coupled to substrate 702, while the microchannel heat exchanger is coupled to the standoffs via threaded fasteners 708. For simplicity, the configuration for attaching the standoffs to the substrate is not shown—any of many well-known physical coupling techniques may be employed for this purpose.

As shown in FIGS. 7a and 7b, the base of microchannel heat exchanger 704 is not directly coupled to the IC die, but rather is thermally coupled via a TIM layer 710. The TIM layer performs several functions. Foremost, it provides a conductive heat transfer path between the microchannel heat exchanger and the top of the die. It also enables the various assembly components to contract and expand in response to temperature changes without inducing any stress on the assembled component while maintaining a good thermal conduction path. For instance, in response to an increase in temperature, most materials expand, while those same materials contract when their temperature is lowered. This rate of expansion/contraction is generally a fixed rate (at least locally) corresponding to the material's coefficient of thermal expansion (CTE). When the CTE for joined materials differs, one material expands or contracts relative to the other, inducing a stress at the joint between the materials. The CTE mismatch can lead to failure at the joint, especially when thermal cycling is occurs.

In most configurations, the material used for the standoffs will be a metal, such as aluminum, steel, or copper. These metals have higher CTE's than typical die materials (semiconductors, such as silicon). As a result, when the temperature increases, the thickness of the TIM layer will increase due to the higher expansion rate of the metal standoff than the die. Since the TIM layer is very compliant and adheres to the two material faces, it easily accommodates this expansion. At the same time, the metal in the microchannel heat exchanger expands horizontally at a different rate than the die does. The relative expansion between the two components is also easily handled by the TIM layer.

Microchannel heat exchanger 704 comprises a metallic, ceramic, or silicon thermal mass 712 having a plurality of open channels formed therein. A plate 714 is employed to close the channels, thereby forming closed microchannels 716. Ideally, the plate should be coupled to the top of the channel walls in a manner that forms a hermitic seal. If necessary, one of several well-known sealants may be disposed between the plate and the tops of the channel walls to facilitate this condition. In one embodiment, plate 714 is soldered to thermal mass 712 (if it is metallic or coated with a solderable layer), in a manner similar to that discussed above with reference to the embodiment of FIG. 7a.

An exemplary package 720 made from sub-assembly 700 is shown in FIG. 7b. In the illustrated embodiment, substrate 702 is mounted to a chip carrier 722 via a plurality of solder balls 724. It will be understood that various other types of packaging may also be employed, including BGA and PGA packages and the like.

Plan and cross-section views illustrating typical channel configurations are shown in FIGS. 8a and 8b, respectively. In general, the channel configuration for a particular implementation will be a function of the heat transfer parameters (thermal coefficients, material thickness, heat dissipation requirements, thermal characteristics of working fluid), working fluid pumping characteristics (temperature, pressure, viscosity), and die and/or heat exchanger area. Although depicted as rectangular in configuration in the figures herein, the actual shape of the channels may include radiused profiles, or may even have substantially circular or oval profiles. The goal is to achieve a two-phase working condition in conjunction with a low and uniform junction temperature and a relatively low pressure drop across the heat exchanger.

Channel configuration parameters for rectangular channel shapes are shown in FIGS. 8a and 8b. The parameters include a width W, a depth D, and a length L. In parallel channel configurations, such as shown in FIG. 8a, respective reservoirs 802 and 804 fluidly coupled to an inlet 806 and outlet 808. In essence, the reservoirs function as manifolds in coupling the microchannels to incoming and outgoing fluid lines. The plurality of microchannels will be formed in a thermal mass having a shape the generally corresponds to the die to which the heat exchanger is thermally coupled. For a rectangular configuration, which is likely to be most common but not limiting, the overall length of the heat exchanger is L_{HE} and the overall width is W_{HE}.

Typically, the microchannels will have a hydraulic diameter (e.g., channel width W) in the hundreds of micrometers (μm), although sub-channels may be employed having hydraulic diameters of 100 μm or less. Similarly, the depth D of the channels will be of the same order of magnitude. It is believed that the pressure drop is key to achieving low and uniform junction temperature, which leads to increasing the channel widths. However, channels with high aspect rations (W/D) may induce flow instability due to the lateral variation of the flow velocity and the relatively low value of viscous forces per unit volume.

In one embodiment target for cooling a 20 mm×20 mm chip, 25 channels having a width W of 700 um, a depth D of 300 um and a pitch P of 800 um are formed in a thermal mass 810 having an overall length L_{HE} of 30 mm and an overall width W_{HE} of 22 mm, with a channel length of 20 mm. The working fluid is water, and the liquid water flow rate for the entire channel array is 20 ml/min.

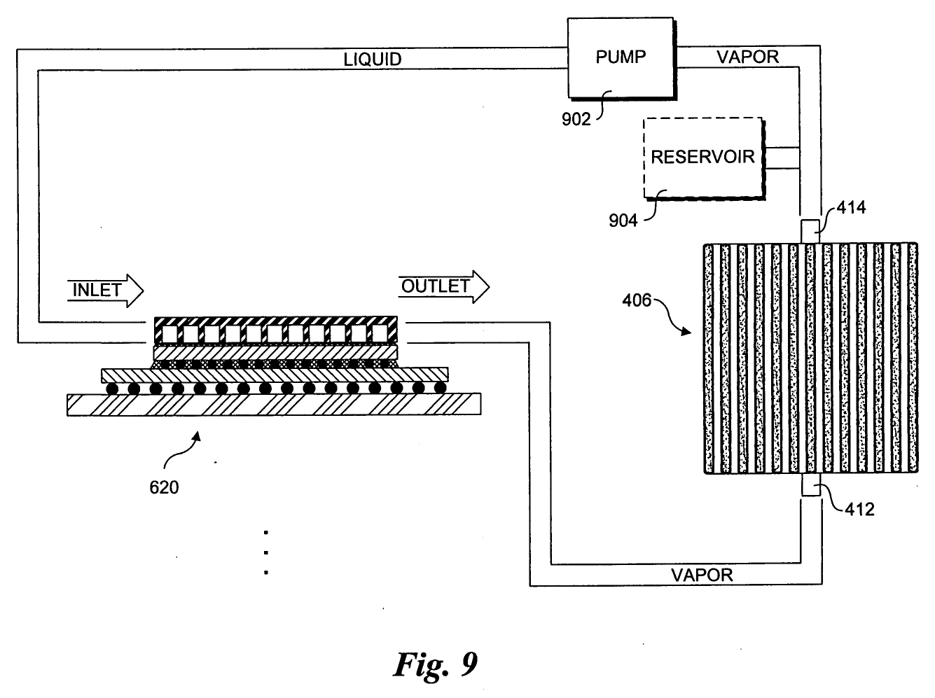

An exemplary cooling system 900 that is illustrative of cooling loop configurations employing various embodiments of the cooling system components discussed herein is shown in FIG. 9. In general, the cooling system may be designed for cooling one or more components, such as IC dies, which produce significant levels of heat in a system, such as a laptop computer, PDA, pocket PC, etc. Typical components for which microchannel heat exchangers might be employed for cooling include higher power components, such as microprocessors, and (relatively) lower power components, such as chip sets, video chips, co-processors, and the like.

Cooling system 900 employs a two-phase working fluid, such as but not limited to water. The working fluid is pumped through the system in liquid its liquid phase via a pump 902. Generally, the pumps used in the closed loop cooling system employing microchannel heat exchangers in accordance with the embodiments described herein may comprise electromechanical (e.g., MEMS-based) or electro-osmotic pumps (also referred to as “electric kinetic” or “E-K” pumps). In one respect, electro-osmotic pumps are advantageous over electromechanical pumps since they do not have any moving parts, which typically leads to improved reliability. Since both of these pump technologies are known in the microfluidic arts, further details are not provided herein.

Pump 902 provides working fluid in liquid form to the inlets of the various microchannel heat exchangers (only one of which is shown). In the illustrated embodiments, this correspond to the single integrated microchannel heat exchanger in an IC package 620A. As denoted by the “ . . . ” continuation marks, there may be a plurality of IC packages employed in an actual system.

Upon passing through the one or more microchannel heat exchangers, a portion of the working fluid is converted from its liquid phase to a vapor phase. This vapor (along with non-converted liquid) exits each microchannel heat exchanger and is routed via appropriate ducting to a heat rejecter. In the illustrated embodiment, the heat rejecter comprises the channeled heat sink 406 corresponding to chassis 400. The vapor is converted back to a liquid in the heat rejecter, which then exits the heat rejecter and is routed to the inlet of pump 902, thus completing the cooling loop. In an optional configuration, a reservoir 904 may be provided to enable additional working fluid to be added to the cooling loop in the event of working fluid losses, such as through evaporation at duct couplings.

The above description of illustrated embodiments of the invention, including what is described in the Abstract, is not intended to be exhaustive or to limit the invention to the precise forms disclosed. While specific embodiments of, and examples for, the invention are described herein for illustrative purposes, various equivalent modifications are possible within the scope of the invention, as those skilled in the relevant art will recognize.

These modifications can be made to the invention in light of the above detailed description. The terms used in the following claims should not be construed to limit the invention to the specific embodiments disclosed in the specification and the claims. Rather, the scope of the invention is to be determined entirely by the following claims, which are to be construed in accordance with established doctrines of claim interpretation.

1. An channeled heat sink, comprising:
a base from which a plurality of hollowed fins extend, each hollowed fin defining a channel fluidly coupled at one end to an inlet and at an opposite end to an outlet, each channel having walls configured to condense a vapor entering the inlet into a liquid upon exiting the outlet.

2. The channeled heat sink of claim 1, wherein the base comprises a hollowed volume comprising a reservoir.

3. The channeled heat sink of claim 1, wherein the inlet and outlet are coupled to the reservoir.

4. The channeled heat sink of claim 1, wherein the heatsink is formed from a metal.

5. The channeled heatsink of claim 1, wherein the heatsink is formed from a plastic.

6. The channeled heatsink of claim 1, wherein the channels comprise microchannels having a hydraulic diameter of less than 1000 micrometers.

7-30. (canceled)
